(19) United States
(12) Patent Application Publication
(10) Pub. No.: US 2010/0068847 A1
(43) Pub. Date: Mar. 18, 2010

(54) METHOD FOR MANUFACTURING AN IMAGE SENSOR

(76) Inventor: Jaime I. Waldman, Pittsford, NY (US)

Correspondence Address: Peter P. Hernandez;Patent Legal Staff, Eastern Kodak Company, 343 State Street, Rochester, NY, 14650-2201, US

(21) Appl. No.: 12/209,356

(22) Filed: Sep. 12, 2008

(51) Int. Cl. H01L 21/00

(52) U.S. Cl. 438/68; 257/E21.001

(57) ABSTRACT

A method for fabricating an image sensor die includes providing a wafer having a plurality of die, each die having a raised portion adjacent to an image area onto which a glass cover will be adhered; and thereafter dicing the wafer so that the plurality of die are separated into individual die.

### FIELD OF THE INVENTION

The present invention generally relates to manufacturing image sensors and more particularly to manufacturing such image sensors in a manner which more efficiently eliminates contamination of the sensor active array.

### BACKGROUND OF THE INVENTION

Referring to FIGS. 1 and 2, there is shown a prior art die 9 after being cut from a wafer. The die 9 includes a silicon die 5 into which an imaging array 3 is disposed, and the imaging array 3 includes a plurality of pixels 4 each for collecting charge in response to light. Bond pads 6 are positioned around the periphery of the die 9.

Although the presently known and utilized method for manufacturing the die 9 is satisfactory, it includes drawbacks. During cutting, the imaging array 3 may become contaminated due to debris produced from the cutting process. Subsequent processes such as soldering may also contribute to contamination of the imaging array. Consequently, a need exists for a manufacturing process which reduces contamination during the cutting process.

### SUMMARY OF THE INVENTION

The present invention is directed to overcoming one or more of the problems set forth above. Briefly summarized, according to one aspect of the invention, the invention resides in a method for fabricating an image sensor die, the method comprising the steps of (a) providing a wafer having a plurality of die, each die having a raised portion adjacent to an image area onto which a glass cover will be adhered; (b) after step (a), dicing the wafer so that the plurality of die are separated into individual die.

It is an object of the present invention to provide a method to reduce cost and reduce particulate contamination on the die during manufacturing.

These and other objects, features, and advantages of the present invention will become apparent to those skilled in the art upon a reading of the following detailed description when taken in conjunction with the drawings wherein there is shown and described an illustrative embodiment of the invention.

### ADVANTAGEOUS EFFECT OF THE INVENTION

The present invention has the advantage of reduced cost and reduced particulate contamination because the image sensor is encapsulated before dicing and subsequent operations are performed.

### BRIEF DESCRIPTION OF THE DRAWINGS

While the specification concludes with claims particularly pointing out and distinctly claiming the subject matter of the present invention, it is believed that the invention will be better understood from the following description when taken in conjunction with the accompanying drawings, wherein:

FIG. 1 is a top vie of a prior art image sensor;

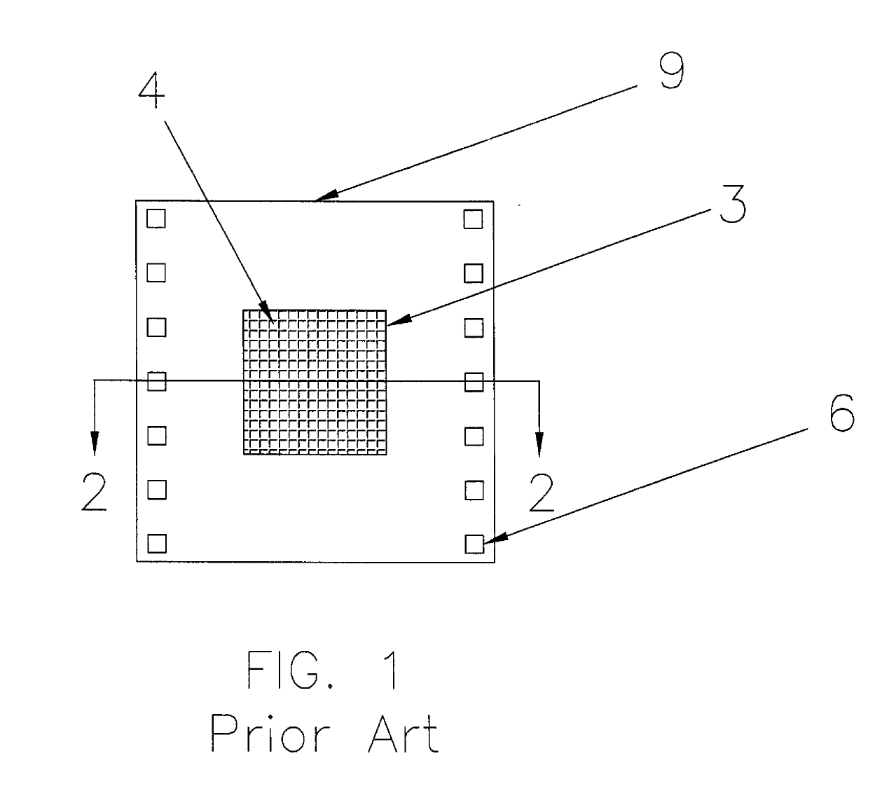

FIG. 2 is side view of FIG. 1 through cross-section 2-2;

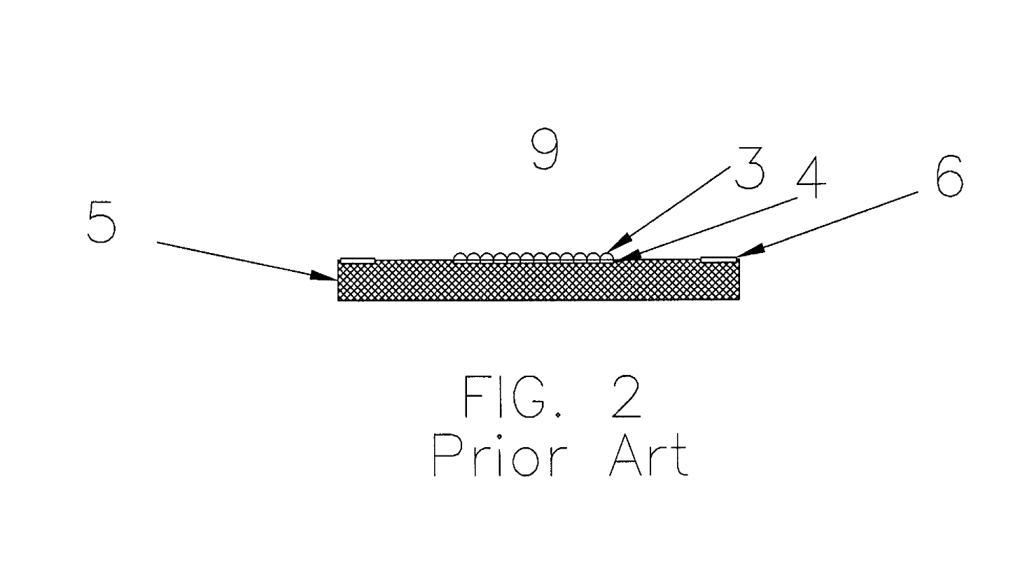

FIG. 3 is a top view of imaging assembly of the present invention;

FIG. 4 is a side view of FIG. 2 through cross-section 4-4;

FIG. 5 is a top view of a second embodiment of the present invention;

FIG. 6 is a side view of FIG. 5 through cross-section 6-6; and

FIG. 7 is a top view of a wafer of the present invention before the wafer is diced.

### DETAILED DESCRIPTION OF THE INVENTION

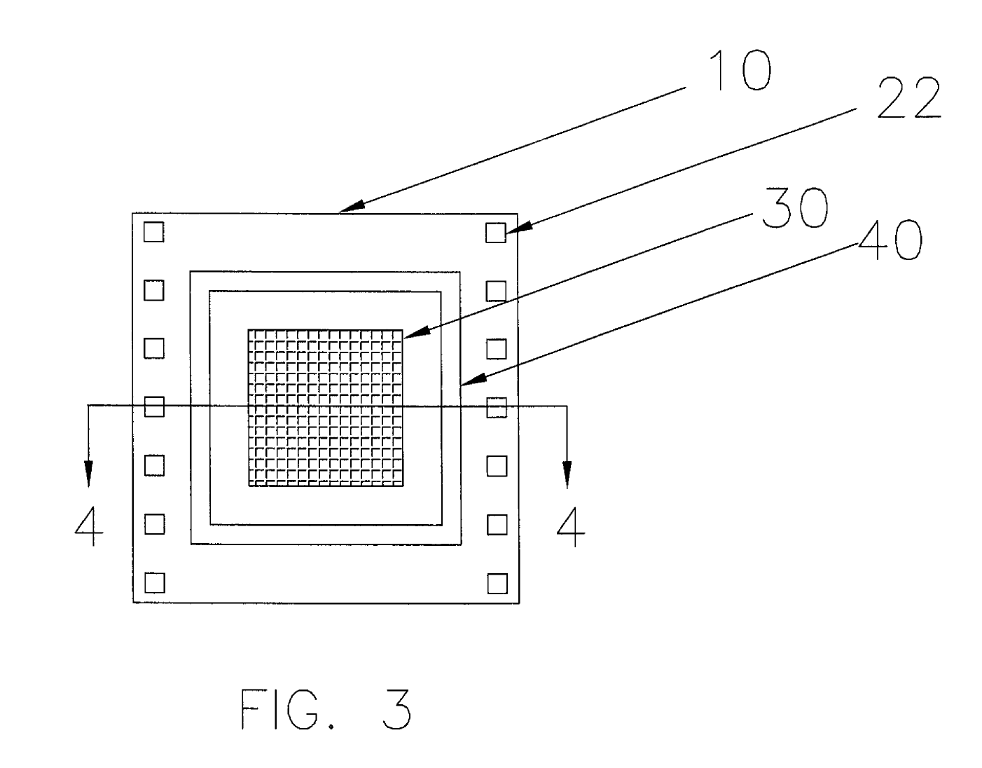

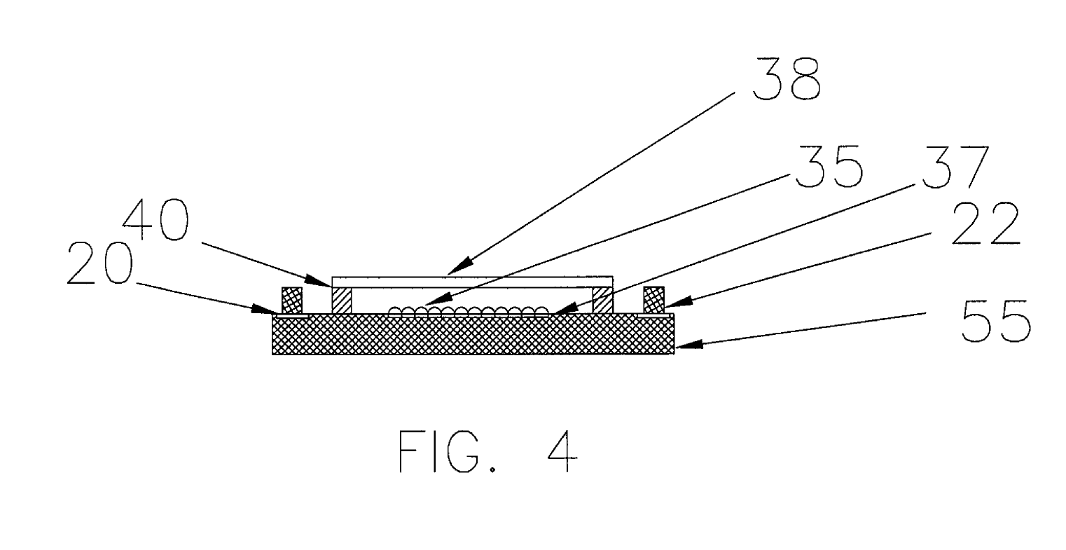

Turning now to FIGS. 3 and 4, there is shown one of a plurality of die 10 after each die has been cut from a wafer 15. Although only one die 10 is shown in FIG. 3 for simplicity of illustration, each die 10 includes the same components as shown in FIGS. 3 and 4. It is instructive to note that the below described components are installed on the die 10 before it is cut from a wafer into individual die, as described hereinbelow. It is further noted that each die 10 is also referred to as an image sensor when, at a minimum, an imaging array 30 is installed.

The die 10 includes the imaging array 30 having a plurality of pixels 37 arranged in a two-dimension array (although a linear one-dimensional array may also be used), and imaging array 30 is disposed in the silicon die 55. Each pixel 37 collects charge in response to incident light. A plurality of micro-lenses 35 are positioned spanning over the plurality of pixels 37 in a one-to-one relationship so that each pixel 37 has one micro-lens 35 spanning over it. A raised portion 40, preferable made of a polymer, extends around the periphery of the die 10 and surrounds the imaging array 30 (i.e., imaging area). Glass 38 is adhered, preferably using epoxy, to the raised portion 40 for encapsulating the imaging array 30 in a manner in which a gap exists between the glass 38 and the micro-lenses 35; the raised portion 40 and glass 38 encapsulates the imaging array 30. Although the first embodiment adheres to the glass 38 before cutting, it maybe done after cutting using a laser or scribe and break process. Extended bond pads 22 are positioned extending from the die surface and on the periphery of two sides of the die 10, opposite each other, for permitting the image sensor 10 to be electrically to components external to the image sensor 10. The extended bond pads 20 are electrically connected to bonds pads 20 which are substantially level or level to the surface of the die 10. The extended bond pads are formed prior to the dicing process. It is noted that the number and position of the extended bond pads 22 and corresponding bond pads 20 may vary and the configuration shown is for illustrative purposes.

In this embodiment, light passes through the glass 38, the micro-lenses 35 and onto the silicon die 55 where the pixels 37 collect charge in response to the incoming light.

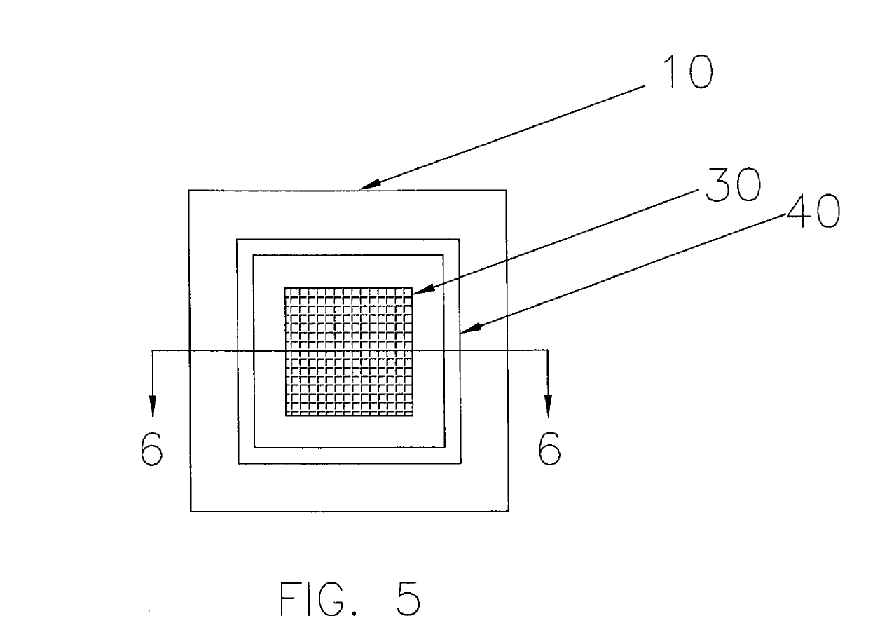

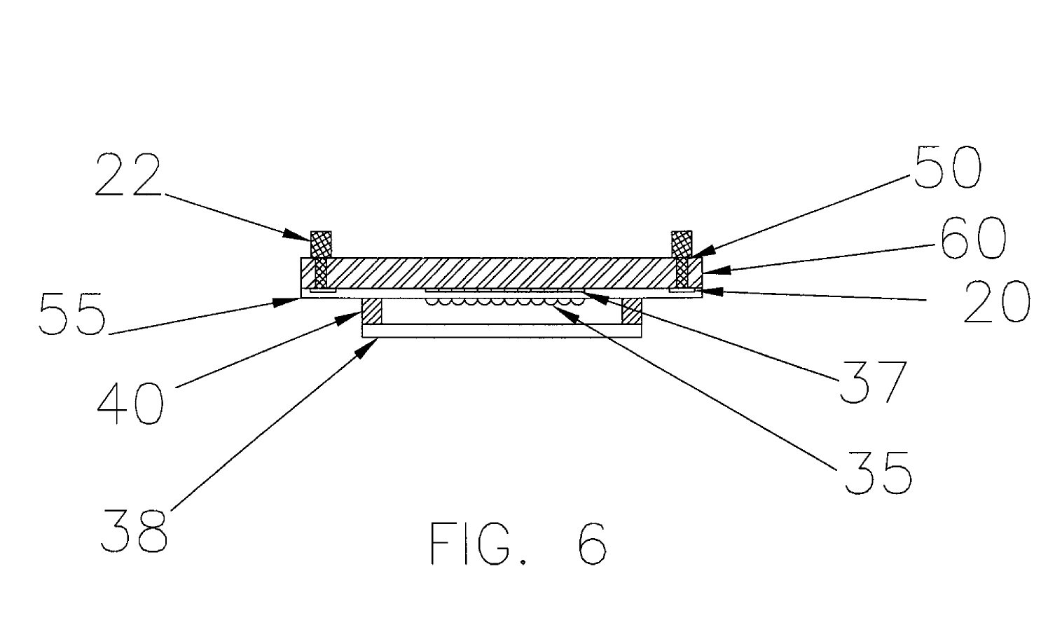

Referring to FIGS. 5 and 6, there is shown a second embodiment of the present invention. This embodiment includes the same elements as described in the first embodiment except that the extended bond pads 22 and bond pads 20 are modified from the design of the first embodiment and extend in the opposite direction so that they do not surround the imaging array 30. The second embodiment also adds a rigid layer 60 and conductive metal 50 as described herein below, which rigid layer 60 and conductive metal 50 are also done before cutting or dicing. It is instructive to note that the silicon die 55 is typically ground extremely thin (before dicing) to allow light to reach the pixel 37 from the back side of the silicon die 55. The rigid layer 60 is attached to the silicon die 55 and functions to provide a sturdy base so that the die 10 is substantially inflexible under normal conditions. The rigid layer 60 is perforated preferably using silicon etching techniques and conductive metal 50 is placed in the perforation portion so that the conductive metal 50 contacts the silicon die 55, and extended bond pads 22 are electrically connected to the conductive metal 50 and bond pads 20. Collectively, the extended bonds pads 22, conductive metal 50 and bond pads 20 function to connect the image sensor 10 to external devices.

In the second embodiment, light first passes through the glass 38, micro-lenses 35 and into and through the portion of the silicon die 55 covering the pixels 37 and eventually onto the pixels 37 which collect charge in response to the incoming light. Passing light in this manner is commonly referred to as backside illumination.

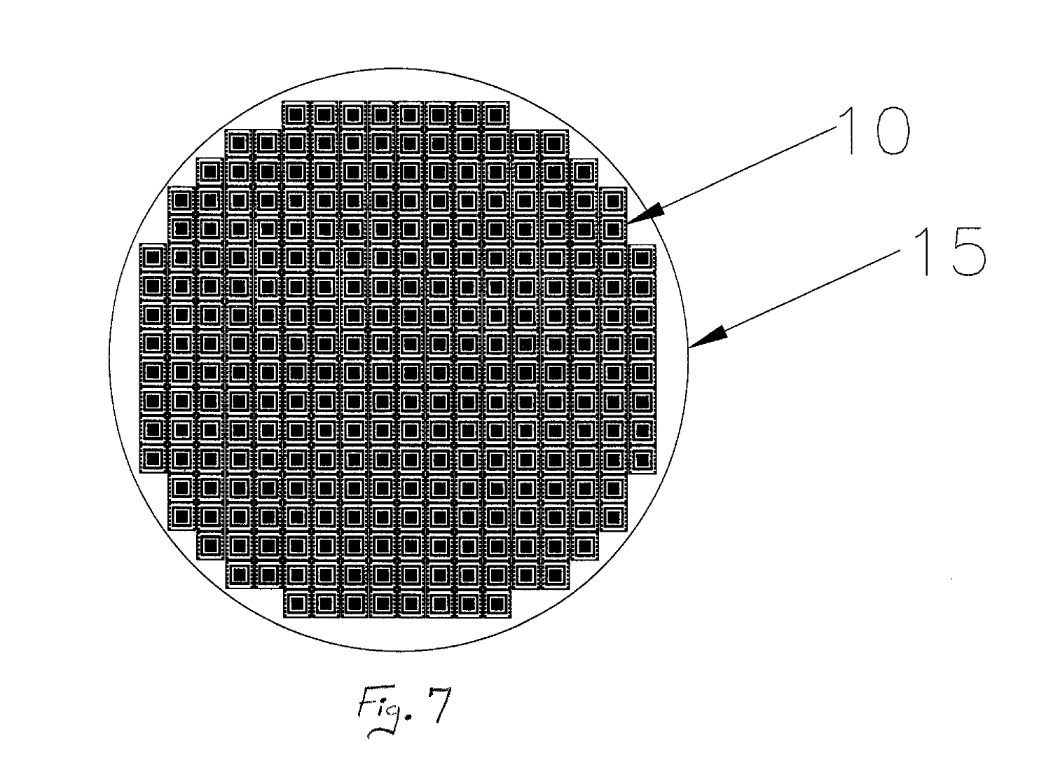

Referring to FIG. 7, there is shown a top view of the wafer 15 before it is cut. The wafer 15 includes a plurality of die 10 which are cut using laser or a scribe and break, both of which are well known in the art. The cutting (i.e., dicing) is performed at the assembly house, and the fabrication facility is where the wafers are fabricated.

It is pointed out that the present invention reduces scratching of the imaging array 30 because the extended bond pads 22 protect the imaging array. Still further, if the glass cover 38 is adhered before cutting, this further eliminates the possibility of contamination.

The invention has been described in detail with particular reference to certain preferred embodiments thereof, but it will be understood that variations and modifications can be effected within the spirit and scope of the invention.

### PARTS LIST

3 (prior art) imaging array
4 (prior art) plurality of pixels
5 (prior art) silicon die
6 (prior art) bond pads
9 (prior art) die
10 die/image sensor
15 wafer
20 bond pads
22 extended bond pads
30 imaging array
35 micro-lenses
37 plurality of pixels
38 glass
40 raised portion
50 conductive metal
55 silicon die
60 rigid layer

1. A method for fabricating an image sensor die, the method comprising the steps of:
(a) providing a wafer having a plurality of die, each die having a raised portion adjacent to an image area onto which a glass cover will be adhered;
(b) after step (a), dicing the wafer so that the plurality of die are separated into individual die.

2. The method as in claim 1, wherein step (b) includes cutting with the die with a laser or a scribe and break.

3. The method as in claim 1 further comprising, before step (b), the step of providing bond pads raised above a surface of the die and disposed around a periphery of the die.

4. The method as in claim 1 further comprising, before step (b), the step of providing micro-tenses spanning the image area.

5. The method as in claim 4 further comprising, before step (b), the step of adhering a glass cover on the raised portion so that a gap exists between the micro-lenses and the glass.

6. The method as in claim 4 further comprising, after step (b), the step of adhering a glass cover on the raised portion so that a gap exists between the micro-lenses and the glass.

7. The method as in claim 1 further comprising, before step (b), the step of providing bond pads level or substantially level to a surface of the die and disposed around a periphery of the die.

8. The method as in claim 1, wherein step (a) is performed at a wafer fabrication facility.

9. The method as in claim 8, wherein step (b) is performed at an assembly house.

10. The method as in claim 1 further comprising a substrate attached to a silicon die in which pixels are disposed.

11. The method as in claim 7, wherein the metal bond pad are extended above the surface of the die and are fabricated on the die before step (b).

12. The method as in claim 1 further comprising the step of placing a rigid layer to the die to provide support for the die.

13. The method as in claim 12 further comprising the step of providing bond pads in the die and providing electrical extensions from the bond pads through the rigid layer for connection to external devices.
